(19) United States
(12) Patent Application Publication
(10) Pub. No.: US 2010/0084566 A1
(43) Pub. Date: Apr. 8, 2010

(54) Electron Column Using A Magnetic Lens Layer Having Permanent Magnets

(76) Inventor: Ho Seob Kim, Incheon (KR)

Correspondence Address: PARK LAW FIRM, 3255 WILSHIRE BLVD, SUITE 1110, LOS ANGELES, CA, 90010, US

(21) Appl. No.: 12/445,257

(22) PCT Filed: Oct. 9, 2007
(86) PCT No.: PCT/KR2007/004918

§ 371 Date: Apr. 10, 2009

(30) Foreign Application Priority Data
Oct. 11, 2006 (KR) 10-2006-0098993

(51) Int. Cl. H01J 37/14

(52) U.S. Cl. 250/396 ML

(57) ABSTRACT

Disclosed herein is an electron column using a magnetic lens layer. The electron column includes a magnetic lens layer for condensing an electron beam using permanent magnets. The magnetic lens layer includes a support plate, an aperture formed through the support plate, and permanent magnets arranged around the aperture and disposed on or inserted into the support plate.

### TECHNICAL FIELD

The present invention relates generally to a lens assembly for an electron column, and, more particularly, to a lens assembly and a focusing method that, in an electron column, pre-focus an electron beam through a magnetic lens layer using permanent magnets and then precisely focus the electron beam, thereby facilitating electron beam focusing and control.

### BACKGROUND ART

Generally, electron columns, including micro-columns, each include an electron emission source for emitting electrons, a source lens for forming an effective electron beam, a deflector for deflecting the electron beam, and a focusing lens for focusing the electron beam. If necessary, an electron column performs focusing using a source lens. Accordingly, focusing is performed using a dedicated focusing lens (for example, an einzel lens) or a source lens.

Such focusing is performed using a lens that includes two or more electrode layers. An einzel lens, which is a typical focus lens, includes three electrode layers, and is used in such a way that voltage is applied to an intermediate electrode layer and the remaining upper and lower electrodes are grounded. Such an einzel lens adjusts focusing based on the magnitude of voltage applied to the intermediate electrode layer, and there are cases where it is necessary to apply high voltage. Meanwhile, the source lens includes three electrode layers, of which the uppermost electrode layer is called an extractor and functions to cause an electron emission source to smoothly emit electrons, the second electrode layer is called an accelerator and functions to accelerate the electrons emitted from the electron emission source, and the last electrode layer is called a limiting aperture and functions to limit or filter electrons so as to form an effective electron beam. In order to perform the above-described functions, the source lens is used in such a way that voltage is applied chiefly to the extractor, and the accelerator and the limiting aperture are grounded. However, in some cases, in an electron column, focusing is performed by applying focusing voltage to the accelerator electrode layer of the source lens. That is, in these cases, focusing is performed using the accelerator and the limiting aperture electrode layer.

FIG. 1 is a sectional view conceptually showing the focusing of an electron beam using an einzel lens, which is a conventional focus lens. The focusing lens, including three electrode layers F1, F2 and F3, is used in such a way that the upper and lower electrode layers F1 and F3 are grounded and separate voltage is applied to the intermediate electrode layer F2. An electron beam B enters the hole of the focusing lens, and is refracted by the voltage applied to the intermediate electrode layer F2, thus being focused. The focusing lens functions as the convex lens of an optical lens using the three electrode layers.

FIG. 2 shows a conventional source lens, which functions to convert electrons, emitted from an electron emission source ‘S’ into an effective beam. A first electrode layer L1 is called an extractor, and functions to cause the electron emission source ‘S’ to smoothly emit electrons. A second electrode layer L2 is called an accelerator, and functions to accelerate the emitted electrons. A third electrode layer L3 is called a limiting aperture, and is to limit passing electrons to form an effective electron beam. The electrode layers of the source lens constitute a basic structure, and perform a basic function in the state in which voltage is applied to a first electrode layer L1, and the other electrode layers L2 and L3 are grounded. However, when necessary, the source lens may perform focusing or a deflecting function, so that the arrangement of electrode layers or the method of applying voltage may change in accordance with the purpose or situation.

In the case of the source lens, focusing is performed using the two electrode layers, so that excessive focusing voltage is applied and it is difficult to precisely control focusing.

Furthermore, a micro-column, which is a very small size electron column, is advantageous in that the voltage used is low. Accordingly, it may not be preferable to apply high voltage, and it may be difficult to precisely control the lens when high voltage is used.

### DISCLOSURE OF INVENTION

### Technical Problem

Accordingly, the present invention has been made keeping in mind the above problems occurring in the prior art, and an object of the present invention is to provide a lens for an electron column that enables easier and more precise control of focusing in the conventional electron column.

Another object of the present invention is to provide a lens for an electron column that, in the electron column, enables the electron beam control of a source lens, focusing, and deflection to be precisely performed using low voltage.

### Technical Solution

In order to accomplish the above objects, the present invention provides an electron column that includes a magnetic lens layer for condensing an electron beam using permanent magnets.

The present invention uses a magnetic lens layer to pre-focus an electron beam in an electron column, and forms a magnetic field through the magnetic lens layer using permanent magnets without requiring separate control and then pre-focuses the electron beam. In the case of an einzel lens, the magnetic lens layer is disposed above the einzel lens, and thus the magnetic lens layer condenses the path of an electron beam toward the center of the path rather than completely focusing the electron beam, thereby performing pre-focusing to some extent. Furthermore, in the case of a source lens, the magnetic lens layer is disposed before an electrode layer to which focusing voltage is applied, and thus an electron beam is caused to be pre-focused under the influence of a magnetic field.

Furthermore, in order to achieve precise electron beam control or easy electron beam control, electrons are condensed or refracted toward the center of the propagation path of an electron beam in an electron column, thereby facilitating the control of the electron beam.

### Advantageous Effects

A magnetic lens layer according to the present invention functions to condense an electron beam, so that, in the focusing of an electron column, precise focusing can be achieved and the voltage used for focusing can be reduced, with the result that the present invention is advantageous with respect to focusing control.

The magnetic lens layer according to the present invention condenses an electron beam, thereby enabling deflection to be more easily controlled.

The support plate of the magnetic lens layer of the present invention is formed of a conductor and is then used in place of a lens layer of a focusing lens, thereby simplifying the structure of an electron column.

### BRIEF DESCRIPTION OF THE DRAWINGS

FIG. 1 is a sectional view conceptually showing the focusing of an electron beam by a conventional focus lens;

FIG. 2 is a sectional view conceptually showing the propagation of an electron beam in the source lens of a conventional electron column;

FIG. 3 is a sectional view conceptually showing the focusing of an electron beam using a magnetic lens layer according to the present invention;

FIG. 4 is a sectional view conceptually showing the condensing of an electron beam using a magnetic lens layer according to the present invention;

FIG. 5 is a plan view showing an example of the magnetic lens layer according to the present invention;

FIG. 6 is a plan view showing examples of a general lens layer that is used together with the magnetic lens layer according to the present invention; and

FIG. 7 is a plan view showing an example of a magnetic lens layer in which the lens layer shown in FIG. 5 is multiplied for use for a multi-electron column.

### MODE FOR THE INVENTION

Various embodiments of the present invention will be described with reference to the accompanying drawings below. Here, it should be noted that the various embodiments are used to illustrate the present invention so that those skilled in the art can easily understand the present invention, and are not intended to limit the rights of the present invention.

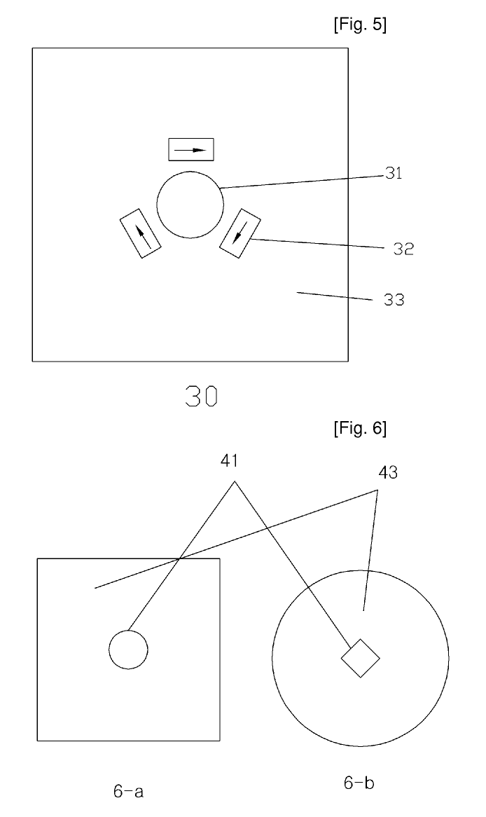

FIG. 3 is a sectional view conceptually showing the sections of lens layers for focusing according to the present invention. FIG. 4 is a sectional view showing an example in which an electrode layer using permanent magnets according to the present invention is used in a source lens. FIG. 5 is a plan view of a magnetic lens layer according to the present invention. FIG. 6 is a plan view of the electrode layer of a general electrostatic lens.

In FIG. 3, the uppermost electrode layer L1 and the lowermost electrode layer L3 are grounded and variable voltage is applied to an intermediate electrode layer L2, thereby performing focusing. A magnetic lens layer M is disposed above the uppermost electrode layer L1 and thus performs pre-focusing. As shown in the drawing, pre-focusing is performed on an electron beam that enters into the magnetic electrode layer M. Pre-focusing is not complete focusing, but functions to condense a diverging and propagating electron beam, and thus can be distinguished from final focusing. Pre-focusing condenses the path of an electron beam radially inwards above the lens layer L2, to which voltage is applied, in the focusing lens, thereby reducing the magnitude of voltage applied to the lens layer L2 and facilitating precise focusing. That is, focusing on a specimen is performed by voltage or current applied to the lens layer L2. A user performs focusing while adjusting applied voltage or the amount of current.

FIG. 5 shows an example of the magnetic lens layer according to the present invention, in which a magnetic lens layer 30 is formed of permanent magnets 32. The three permanent magnets 32 are arranged in series in a circle around a central aperture 31, and perform pre-focusing on an electron beam that passes through the aperture 31. The intensity of pre-focusing is determined depending on the magnetic force of the permanent magnets. The permanent magnets 32 may be arranged by attaching and inserting them onto and into a support plate 33. The support plate 33 may be formed of an insulator, such as Pyrex, or a semiconductor silicon plate. The support plate 33 is not particularly influenced by material as long as no influence is exerted on the magnetic field of the permanent magnets 32. The support plate 33 requires that the central aperture 31 can be aligned with the other electrode layers of the focusing lens. Accordingly, the support plate 33 may be made of silicon, like the other lens layers, or may be formed of a thin metal plate. The magnetic lens layer of the present invention uses permanent magnets to control an electron beam, so that separate control is not required and the magnetic lens layer is used in such a way as to previously select the magnetic force of the permanent magnets and condense an electron beam to an extent corresponding to the magnetic force. Of course, the arrangement of the permanent magnets 32 shown in FIG. 3 may be changed and used in various ways according to the method of arranging magnetic lenses. However, the permanent magnets must be arranged such that an electron beam B passing through the central aperture 31 can be condensed.

FIG. 4 is a longitudinal section showing an example in which a magnetic lens layer according to the present invention is used in the source lens of FIG. 2.

In the lens layers of FIG. 4, a magnetic lens layer M according to the present invention is disposed between the uppermost electrode layer L1 of FIG. 2 and the lower electrode layer L2 below the electrode layer L1. An electron beam is made to enter the apertures of the lens by the electrode layer L1, and the entering electron beam is condensed radially inwards by the magnetic lens layer M. Accordingly, the electron beam, radiating from an electron emission source ‘S’, is refracted toward a central axis. As a result, a larger number of electrons can pass through the aperture of the last lens layer L3, and thus the number of electrons of the electron beam increases, so that the intensity of a probe beam reaching a specimen increases. If the lens layer L2 performs focusing, a pre-focusing function can be performed, as in the case of FIG. 3.

FIG. 6 shows examples of an electrostatic lens layer that can be used along with the magnetic lens layer of the present invention, wherein circular and square apertures 41 are respectively formed in square and circle-shaped lens layers 43. However, the circle and square of the present drawing are only examples, and thus polygons, such as a triangle and a rectangle, and various shapes, such as a circle and an ellipse, may be used. Meanwhile, the aperture may have a certain shape as needed. The magnetic lens layer of the present invention may be manufactured in accordance with the outer shape and shape of the apertures of the other lens layers. On a certain occasion, the magnetic lens layer may be manufactured such that the aperture is formed to have a circular shape and the magnetic lens layer performs only pre-focusing. The magnetic lens layer according to the present invention can be used in all of an electrostatic lens, a magnetic lens, and an electromagnetic field lens.

The magnetic lens layer using permanent magnets according to the present invention can be used in a source lens as well as a focusing lens. Since the function of the magnetic lens layer according to the present invention is to perform condensing using magnetic force inherent in the permanent magnets, the magnetic lens layer can be used in elements that require such condensing. A representative example in which the magnetic lens layer of the present invention can be used is the case where the magnetic lens layer is used to function to pre-focus an electron beam in a focusing process. However, in another example, the magnetic lens layer of the present invention may be used to previously condense a beam before a deflector, thereby facilitating deflection.

First, with regard to focusing, the magnetic lens layer of the present invention causes an electron beam to be previously condensed before it reaches an electrode layer to which variable voltage or current is applied so as to perform focusing, as shown in FIG. 3, so that focusing is not only facilitated but precise focusing control is also enabled. Although, in an electron column, focusing is generally performed by a separate focusing lens, there are cases where focusing is performed by the source lens regardless of using a separate focusing lens, in which case the magnetic lens layer of the present invention may be disposed and used before an electrode layer to which voltage or current is applied so as to perform focusing.

Meanwhile, in an electron column, a deflector is used to scan an electron beam onto a specimen. In this case, since an electron beam passes through the center portion of the deflector, the magnetic lens layer according to the present invention may be disposed before the deflector so that the deflector performs deflection by condensing an electron beam more easily.

The magnetic lens layer according to the present invention does not require separate wiring or grounding. However, in some cases, when a support plate made of conductive material, such as metal, or highly doped silicon is used, the magnetic lens layer is grounded, is not separately controlled, and may perform the acceleration of an electron beam or function as part of a lens.

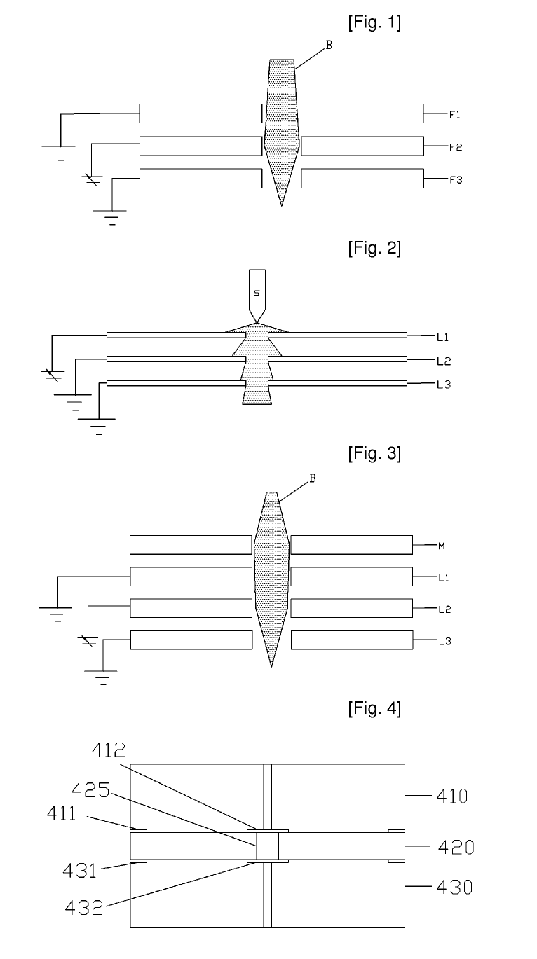

In particular, in the case of an electrostatic lens, a specific lens layer performs functions in a grounded state, like the top and bottom layers of the focusing lens of FIG. 1, which are grounded and used, so that it is possible to perform the same functions at the same time. That is, the magnetic lens layer of the present invention may be used in place of the uppermost layer of the focusing lens shown in FIG. 1. In this case, the support plate for the permanent magnets may be made of conductive material or highly doped silicon.

Furthermore, the magnetic lens layer of the present invention is configured such that permanent magnets are arranged in a layer. Accordingly, for the case of FIG. 4, when permanent magnets are adhered to or combined with the bottom of the uppermost electrode layer L1, like the magnets of FIG. 5, a function identical to that of the case of FIG. 4 can be performed. That is, in the case of an existing electrostatic lens, the magnetic lens layer of the present invention may be formed by arranging permanent magnets on the bottom or top of the electrostatic lens rather than forming a separate electrode layer. Of course, in the case of the electrostatic lens, an insulating layer or a gap may be provided therein, which makes it possible to arrange and use permanent magnets on Pyrex or the like at some distance. Since, in the existing electrostatic lens, electrode layers are stacked one on top of another with insulating layers, such as Pyrex layers, interposed therebetween, permanent magnets may be arranged on an insulating layer such as the Pyrex layer.

If the magnetic lens layer, including permanent magnets, according to the present invention is manufactured in the same manner as the lens layer of a multi-electron column, the magnetic lens layer can be used in the multi-electron column.

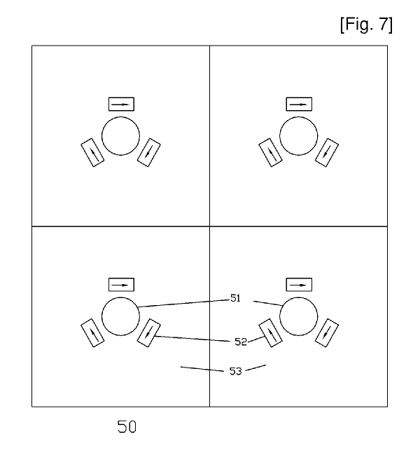

FIG. 7 shows the case where a plurality of permanent magnets 52 is disposed around a plurality of apertures 51 so that the magnetic lens layer 30 shown in FIG. 5 can be used for a multi-electron column. This type of layer is manufactured using a wafer, like the other lens layers.

The permanent magnets may be manufactured through a semiconductor manufacturing process, or may be formed on the support plate 53 through a separate adhering process. The support plate 53 may be composed of a single layer, and may contain the aperture 51 along with the permanent magnets 52 for each electron column.

Although the support plate 43 may be formed of a metal plate, it may be formed of highly doped silicon, an insulating layer, such as Pyrex, or a general silicon layer so as to manufacture the support plate 43 in a manner that can be conducted in a semiconductor manufacturing process.

### INDUSTRIAL APPLICABILITY

An electron column of the present invention could be used for a semiconductor lithography, or an inspection equipment using an electron column.

1. An electron column, comprising:
a magnetic lens layer having permanent magnets for condensing an electron beam.

2. The electron column as set forth in claim 1, wherein the magnetic lens layer comprises a support plate, an aperture formed through the support plate, and permanent magnets arranged around the aperture and disposed on or inserted into the support plate.

3. The electron column as set forth in claim 2, wherein the support plate is a conductive layer or an electrostatic lens layer made of conductive material or highly doped silicon.

4. The electron column as set forth in claim 3, wherein the magnetic lens layer is disposed between electrode layers of a lens, between lenses, or before a deflector.

5. The electron column as set forth in claim 3, wherein the magnetic lens layer is disposed before a lens for focusing the electron beam, and pre-focuses the electron beam.

6. The electron column as set forth in claim 3, wherein the magnetic lens layer is disposed before a deflector, and condenses the electron beam, so that the electron beam is deflected by condensing the electron beam at the time of deflection.

7. The electron column as set forth in claim 2, wherein the magnetic lens layer is disposed between electrode layers of a lens, between lenses, or before a deflector.

8. The electron column as set forth in of claim 2, wherein the magnetic lens layer is disposed before a lens for focusing the electron beam, and pre-focuses the electron beam.

9. The electron column as set forth in of claim 2, wherein the magnetic lens layer is disposed before a deflector, and condenses the electron beam, so that the electron beam is deflected by condensing the electron beam at the time of deflection.

10. The electron column as set forth in of claim 1, wherein the magnetic lens layer is disposed between electrode layers of a lens, between lenses, or before a deflector.

11. The electron column as set forth in claim 1, wherein the magnetic lens layer is disposed before a lens for focusing the electron beam, and pre-focuses the electron beam.

12. The electron column as set forth in of claim 1, wherein the magnetic lens layer is disposed before a deflector, and condenses the electron beam, so that the electron beam is deflected by condensing the electron beam at the time of deflection.
